(19) United States
(12) Patent Application Publication
(10) Pub. No.: US 2019/0172920 A1
(43) Pub. Date: Jun. 6, 2019

(54) JUNCTIONLESS TRANSISTOR DEVICE AND METHOD FOR PREPARING THE SAME

(71) Applicant: NANYA TECHNOLOGY CORPORATION, New Taipei City (TW)

(72) Inventors: Tsung-Yu TSAI, New Taipei City (TW); Ching-Chia HUANG, Taipei City (TW); Kung-Ming FAN, Taoyuan City (TW)

(21) Appl. No.: 15/862,158

(22) Filed: Jan. 4, 2018

Related U.S. Application Data
(60) Provisional application No. 62/595,248, filed on Dec. 6, 2017.

(51) Int. Cl. H01L 29/423; H01L 29/78; H01L 29/66

(52) U.S. Cl. CPC H01L 29/42392; H01L 29/7809; H01L 29/7832; H01L 29/66795; H01L 29/785; H01L 29/7835

(57) ABSTRACT

A functionless transistor device includes a semiconductor substrate, a channel, a first source/drain, a second source/drain, a gate and a gate dielectric layer. The channel includes a first channel extending in a lateral direction, and a second channel extending in a vertical direction. The first source/drain is in contact with the first channel. The second source/drain is in contact with the second channel. The channel, the first source/drain and the second source/drain have the same doping type. The gate is disposed over an upper surface of the first channel and side surfaces of the second channel, and the gate has a second doping type opposite to the first doping type. The gate dielectric layer is disposed between the gate and the channel.

### PRIORITY CLAIM AND CROSS-REFERENCE

This application claims the benefit of provisional application Ser. 62/595,748 filed on Dec. 6, 2017, entitled “JUNCTIONLESS TRANSISTOR DEVICE AND METHOD FOR PREPARING THE SAME” the disclosure of which is hereby incorporated by reference in its entirety.

### TECHNICAL FIELD

The present disclosure relates to a junctionless transistor device and method for preparing the same, and more particularly, to a gate-all-around (GAA) junctionless transistor device with a vertical channel and method for preparing the same.

### DISCUSSION OF THE BACKGROUND

A conventional Metal-Oxide-Semiconductor Field-Effect Transistor (MOSFET) transistor device is a four terminal device, which includes a gate terminal, a source terminal, a drain terminal and a bulk (substrate) terminal. The source/drain (S/D) and the channel of the MOSFET transistor device have opposite doping types. Accordingly, a depletion region can generate in the interface between the S/D and the channel. When the MOSFET transistor device is scaled down, the depletion region will “punch,” leading to high leakage current, worse subthreshold swing, and Drain Induced Barrier Lowering (DIBL) effect. In other words, short channel effect (SCE) becomes severe. In addition, another depletion region may also exist in the interface between the S/D and the bulk.

In a conventional fabrication process, an annealing process is required to repair the defect that appears subsequent to a high-energy implantation process for forming the S/D. The junction depth and the doping concentration gradient, however, are affected by the annealing process. This may deteriorate the diode (between the S/D and the channel or between the S/D and the bulk) properties, which may increase leakage current.

This Discussion of the Background section is for background information only. The statements in this Discussion of the Background are not an admission that the subject matter disclosed in this section constitutes a prior art to the present disclosure, and no structure of this section may be used as an admission that any structure of this application, including this Discussion of the Background section, constitutes prior art to the present disclosure.

### SUMMARY

One aspect of the present disclosure provides a junctionless transistor device including a semiconductor substrate, a channel, a first source/drain, a second source/drain, a gate and a gate dielectric layer. The semiconductor substrate has a surface. The channel is disposed over the semiconductor substrate. The channel includes a first channel extending in a lateral direction substantially parallel to the surface of the semiconductor substrate, and a second channel extending in a vertical direction substantially perpendicular to the surface of the semiconductor substrate. The first channel and the second channel are in contact at one end, and the channel has a first doping type. The first source/drain is disposed over the semiconductor substrate, and is in contact with the first channel, wherein the first source/drain has the first doping type. The second source/drain is disposed over the second channel, and is in contact with the second channel. The second source/drain has the first doping type. The gate is disposed over, an upper surface of the first channel and side surfaces of the second channel, and the gate has a second doping type opposite to the first doping type. The gate dielectric layer is disposed between the gate and the channel.

In some embodiments, a doping concentration of the first source/drain, a doping concentration of the second source/drain and a to doping concentration of the channel are substantially the same.

In some embodiments, a doping concentration of the gate is higher than a doping concentration of the channel.

In some embodiments, the semiconductor substrate includes a doped well under the channel, and the doped well has the second doping type.

In some embodiments, a doping concentration of the doped well is lower than a doping concentration of the Channel.

In some embodiments, the junctionless transistor device further includes a first electrical contact electrically connected to the first source/drain, and a second electrical contact electrically connected to the second source/drain.

In some embodiments, the gate surrounds a plurality of side surfaces of the second channel.

Another aspect of the present disclosure provides a method for preparing a junctionless transistor device. The method includes the following steps. A semiconductor substrate is provided. A semiconductor doped structure is formed over the semiconductor substrate. The semiconductor doped structure has a first doping type. The semiconductor doped structure includes a first doped structure extending in a lateral direction substantially parallel to a surface of the semiconductor substrate, and a second doped structure extending in a vertical direction substantially perpendicular to the surface of the semiconductor substrate. A gate dielectric layer and a gate are formed over the semiconductor doped structure. The gate has a second doping type opposite to the first doping type.

In some embodiments, the forming the semiconductor doped structure over the semiconductor substrate includes forming a doped region having the first doping type in the semiconductor substrate, and patterning the doped region to form the semiconductor doped structure.

In some embodiments, the gate dielectric layer and the gate cover an upper surface of the first doped structure and side surfaces of the second doped structure, and expose an upper surface of the second doped structure.

In some embodiments, the forming the gate dielectric layer and the gate over the semiconductor doped structure includes forming the gate dielectric layer over the semiconductor doped structure; forming the gate over the gate dielectric layer; doping the gate; and partially removing the gate and the gate dielectric layer to expose the upper surface of the second doped structure.

In some embodiments, the forming the gate dielectric layer over the semiconductor doped structure comprises thermally growing a thermal oxide layer over the semiconductor doped structure.

In some embodiments, a doping concentration of the first doped structure and a doping concentration of the second doped structure are substantially the same.

In some embodiments, a doping concentration of the gate is higher than a doping concentration of the semiconductor doped structure.

In some embodiments, an end of the first doped structure is configured as a first source/drain, an end of the second doped structure is configured as a second source/drain, and the first doped structure and the second doped structure are configured as a channel.

In some embodiments of the present disclosure, the junctionless transistor device is a gate-all-around junctionless field effect transistor (GAAJLFET) device with a vertical channel structure. The GAAJLFET device is advantageous for its lower thermal budget, lower leakage current, greater on/off ratio and greater swing. The vertical channel structure can conserve layout area, and can be integrated into various electronic device fabrications such as DRAM fabrication.

In contrast, an FET transistor device with PN junction faces short channel effect (SCE) when scaling down, and the SCE may result in high leakage current, worse subthreshold swing and Drain Induced Barrier Lowering (DIBL) effect.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description, and:

FIG. 1 is a flow diagram illustrating a method for preparing a junctionless transistor device, in accordance with some embodiments is of the present disclosure;

FIG. 2A, FIG. 2B, FIG. 2C, FIG. 2D, FIG. 2E and FIG. 2F are schematic diagrams at one or more of various steps of preparing a junctionless transistor device, in accordance with some embodiments of the present disclosure;

FIG. 3A is a perspective view of a junctionless transistor device, in accordance with some embodiments of the present disclosure;

FIG. 3B is a cross-sectional view of a junctionless transistor device along a line A-A of FIG. 3A, in accordance with some embodiments of the present disclosure;

FIG. 3C is a top view of a junctionless transistor device, in accordance with some embodiments of the present disclosure; and

FIG. 4 is a plot illustrating an Id-Vg curve of a functionless transistor device when Vd=1V, in accordance with some embodiments of the present disclosure,

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, is even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

As used herein, the term “junctionless transistor device” refers to a transistor device in which the source/drain and the channel have the same doping type.

As used herein, the terms “patterning” and “patterned” are used in the present disclosure to describe an operation of forming a predetermined pattern on a surface. The patterning operation includes various steps and processes and varies in accordance with different embodiments. In some embodiments, a patterning process is adopted to pattern an existing film or layer. The patterning process includes forming a mask on the existing film or layer and removing the unmasked film or layer with an etching or other removal process. The mask can be a photoresist, or a hard mask. In some embodiments, a patterning process is adopted to form a patterned layer directly on a surface. The patterning process includes forming a photosensitive film on the surface, conducting a photolithography process including an exposure process and a developing process, and performing an etching process.

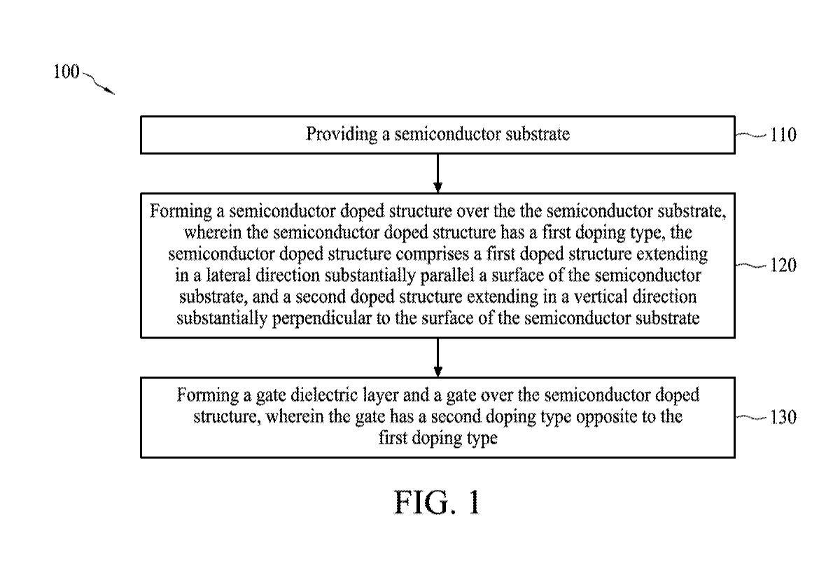

FIG. 1 is a flow diagram illustrating a method for preparing a junctionless transistor device, in accordance with some embodiments of the present disclosure. As shown in FIG. 1, the method 100 for preparing a junctionless transistor device begins with a step 110 in which a semiconductor substrate is provided. The method 100 for preparing a junctionless transistor device proceeds with a step 120 in which a semiconductor doped structure is formed over the semiconductor substrate. The semiconductor doped structure has a first doping type, the semiconductor doped structure includes a first doped structure extending in a lateral direction substantially parallel to a surface of the semiconductor substrate, and a second doped structure extending in a vertical direction substantially perpendicular to the surface of the semiconductor substrate. The method 100 for preparing a junctionless transistor device continues with a step 130 in which a gate dielectric layer and a gate are formed over the semiconductor doped structure. The gate has a second doping type opposite to the first doping type.

The method 100 is merely an example, and is not intended to limit the present disclosure beyond what is explicitly recited in the claims. Additional steps can be provided before, during, and after the method 100, and some operations described can be replaced, eliminated, or moved around for additional embodiments of the method.

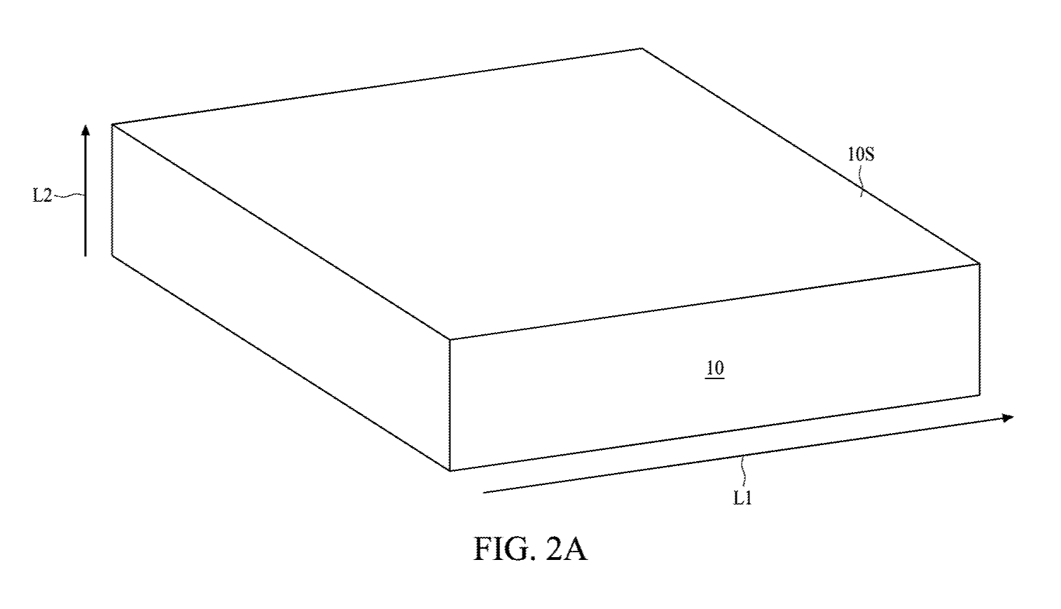

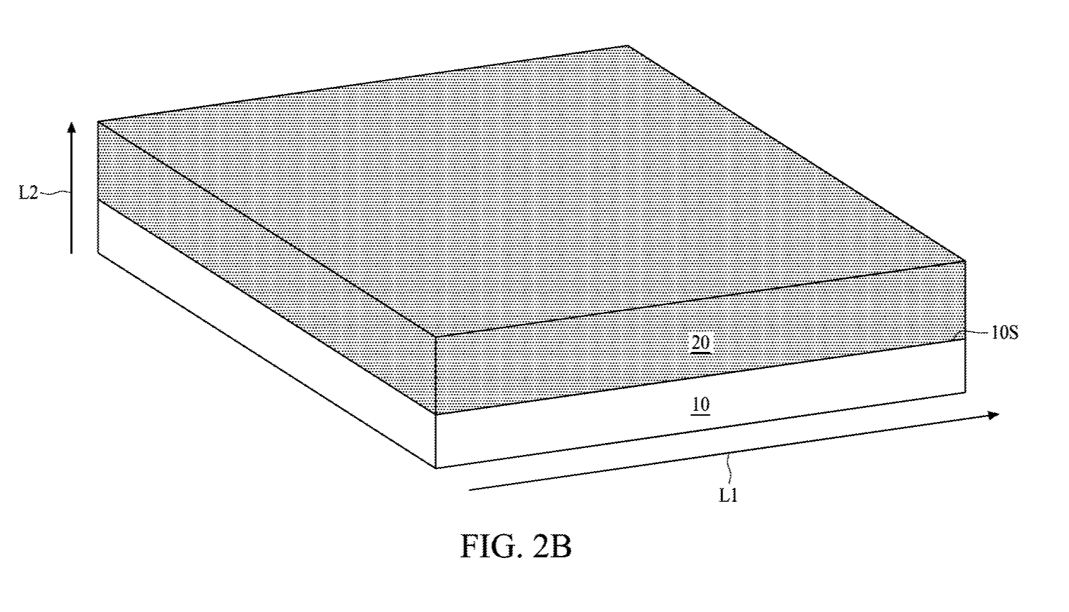

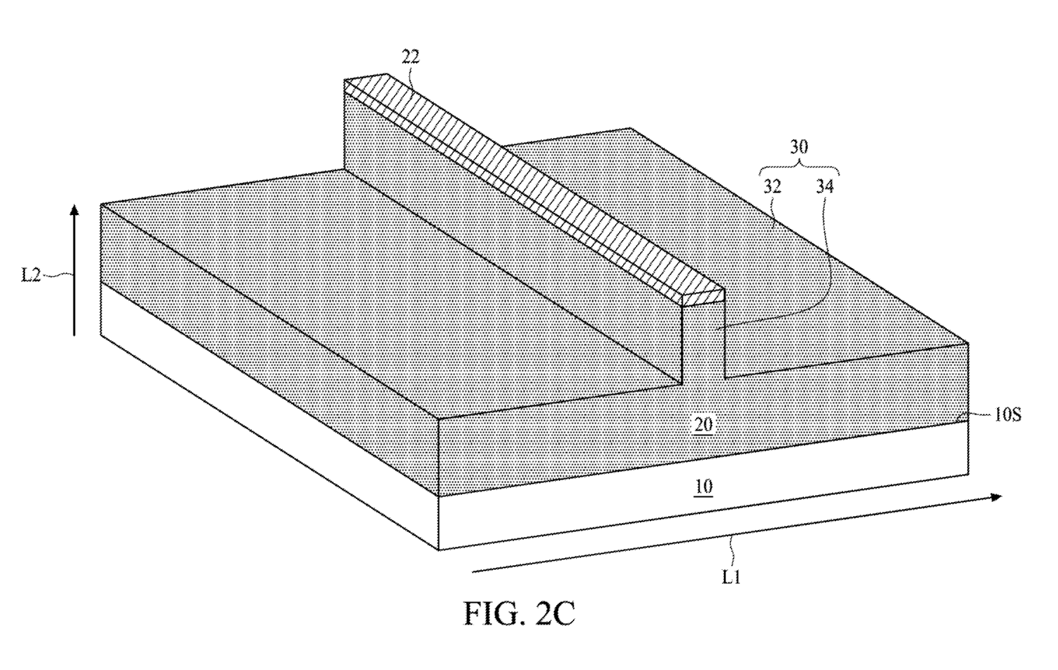

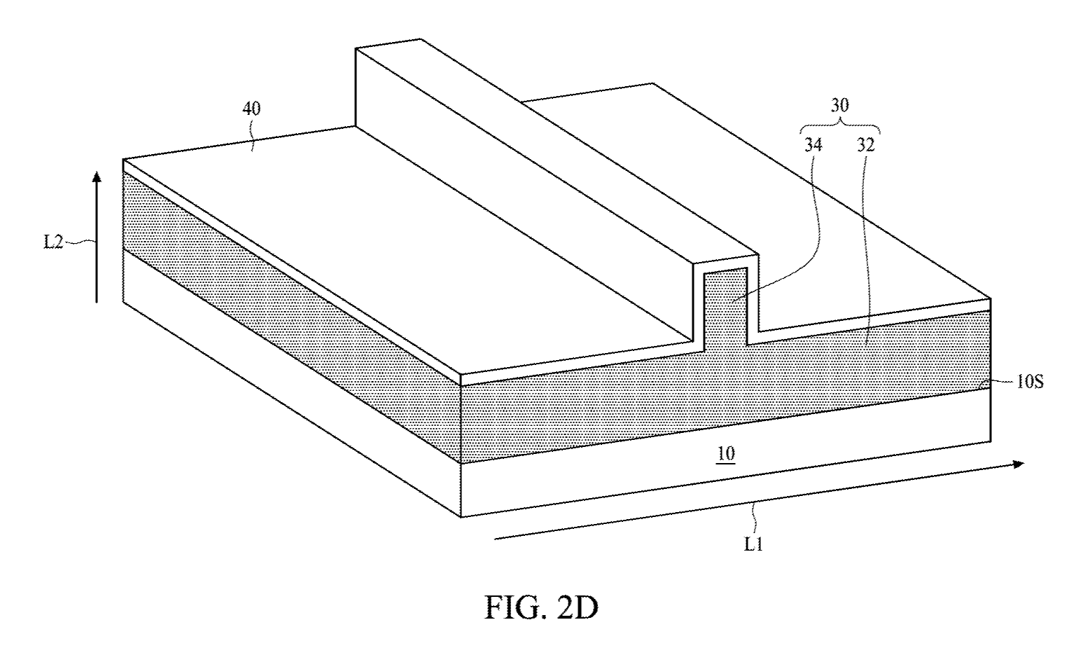

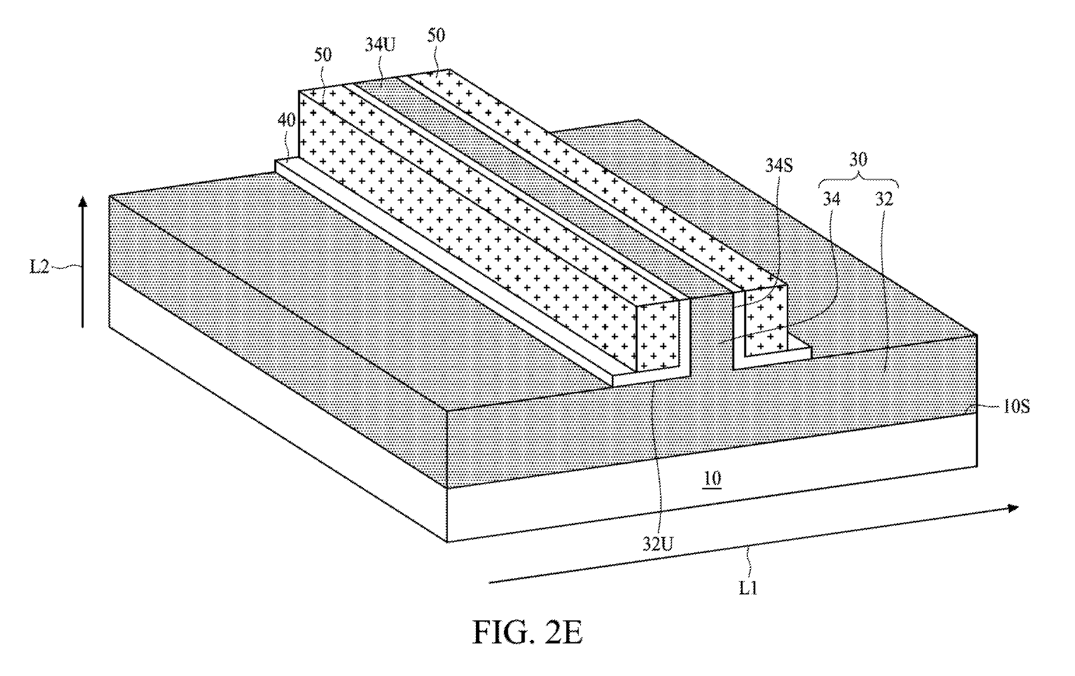

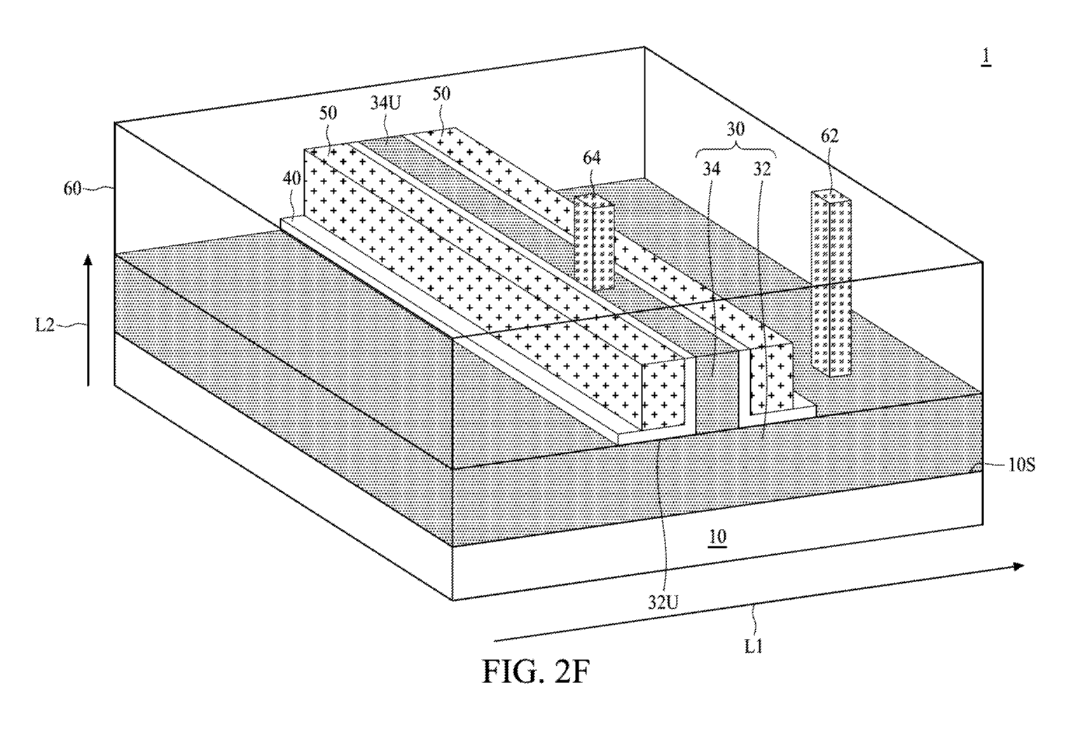

FIG. 2A, FIG. 2B, FIG. 2C, FIG. 2D, FIG. 2E and FIG. 2F are schematic diagrams at one or more of various steps of preparing a junctionless transistor device, in accordance with some embodiments of the present disclosure. As shown in FIG. 2A, a substrate 10 is provided. The substrate 10 may include a semiconductor substrate. By way of examples, the material of the substrate 10 may include elementary semiconductor such as silicon or germanium; compound semiconductor such as silicon germanium, silicon carbide, gallium arsenic, gallium phosphide, indium phosphide or indium arsenide; combinations thereof; or other suitable material.

As shown in FIG. 2B, a doped region 20 is formed in the semiconductor substrate 10. In some embodiments, the doped region 20 has a first doping type, while the semiconductor substrate 10 has a second doping type opposite to the first doping type. By way of example, the first doping type may be N type, while the second doping type is P type. In some embodiments, the doped region 20 may be formed by an implantation process, or other suitable doping technique. In some embodiments, the depth of the doped region 20 may be controlled by adjusting the doping energy of the implantation process. In some embodiments, a portion of the semiconductor substrate 10 may be a doped well (not shown) having the second doping type, and the doped well may be in contact with the doped region 20.

As shown in FIG. 2G, the doped region 20 is patterned to form a semiconductor doped structure 30. In some embodiments, the doped region 20 is patterned by photolithography and etching techniques. For example, a sacrificial layer 22 is formed over the doped region 20. The sacrificial layer 22 may include a hard mask layer such as a silicon nitride layer, which partially exposes the doped region 20. Next, the doped region 20 exposed through the sacrificial layer 22 is etched to form the semiconductor doped structure 30.

In some embodiments, the semiconductor doped structure 30 includes a first doped structure 32 and a second doped structure 34 connected to each other. The first doped structure 32 is lying over the semiconductor substrate 10, and extends in a lateral direction L1 substantially parallel to a surface 10S of the semiconductor substrate 10. The second doped structure 34 extends in a vertical direction L2 substantially perpendicular to the surface 10S of the semiconductor substrate 10. By way of example, the semiconductor doped structure 30 is an L-shaped structure, or a T-shaped structure.

In some embodiments, the first doped structure 32 and the second doped structure 34 are in contact with each other. An end of the first doped structure 32 may be configured as a first source/drain, and an end of the second doped structure 34 may be configured as a second source/drain. The first doped structure 32 and the second doped in structure 34 may be configured as a channel. Since the first doped structure 32 and the second doped structure 34 are formed from the doped region 20, the doping concentration of the first doped structure 32 and the doping concentration of the second doped structure 34 are substantially the same. Accordingly, the interface between the channel and the first source/drain and the interface between the channel and the second source/drain are functionless. In addition, an extra implantation process and an annealing process for doping the first source/drain and the second source/drain may be omitted. Accordingly, thermal budget can be reduced. After the semiconductor doped structure 30 is formed, the sacrificial layer 22 is removed.

A gate dielectric layer and a gate are formed over the semiconductor doped structure. In some embodiments, the gate dielectric layer and the gate may be formed by the following operations. As shown in FIG. 2D, a gate dielectric layer 40 is formed over the semiconductor doped structure 30. The gate dielectric layer 40 may include a. thermal oxide layer such as a silicon oxide layer formed by thermal growing. In some embodiments, the gate dielectric layer 40 may be formed by thermal oxidization, but the disclosure is not limited thereto.

As shown in FIG. 2E, a gate 50 is formed over the gate dielectric layer 40. In some embodiments, the material of the gate 50 may include a semiconductor material such as polycrystalline silicon. The gate 50 has a second doping type opposite to the first doping type of the semiconductor structure 30. In some embodiments, the gate 50 is doped by an implantation process. In some embodiments, the doping concentration of the gate 50 is higher than the doping concentration of the semiconductor doped structure 30.

The gate 50 and the gate dielectric layer 40 are then partially removed to expose an upper surface 34U of the second doped structure 34, while side surfaces 34S of the second doped structure 34 and an upper surface 32U of the first doped structure 32 are covered by the gate dielectric layer 40 and the gate 50. In some embodiments, the gate 50 and the gate dielectric layer 40 may cover two surfaces 34S of the second doped structure 34, or may surround the surfaces 34S of the second doped structure 34. In some embodiments, the gate 50 and the gate dielectric layer 40 may be partially removed by photolithography and etching techniques.

As shown in FIG. 2F, at least one dielectric layer 60 may be formed over the semiconductor substrate 10. In some embodiments, a first electrical contact 62 and a second electrical contact 64 may be formed to fabricate a junctionless transistor device 1 of some embodiments of the present disclosure. The first electrical contact 62 may penetrate through the at least one dielectric layer 60 and be electrically connected to a portion of the first doped structure 32 (i.e., the first source/drain). The second electrical contact 64 may penetrate through the at least one dielectric layer 60 and be electrically connected to a portion of the second doped structure 34 (i.e., the second source/drain).

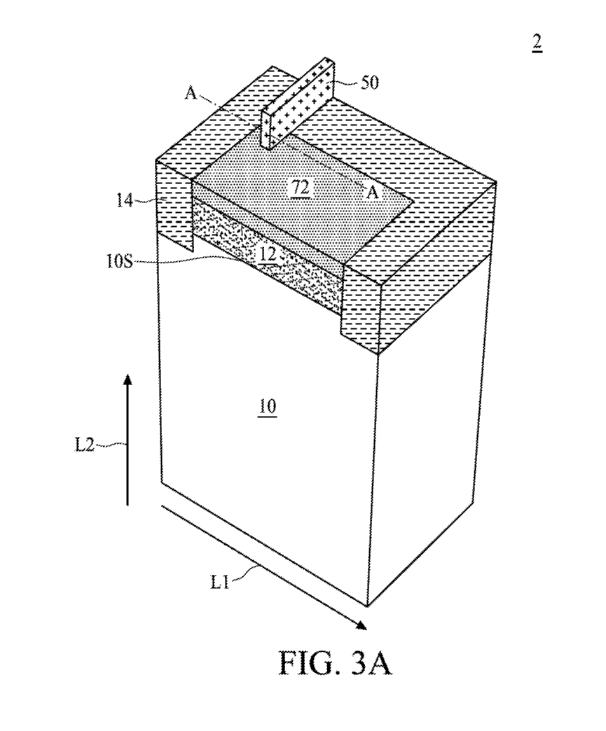

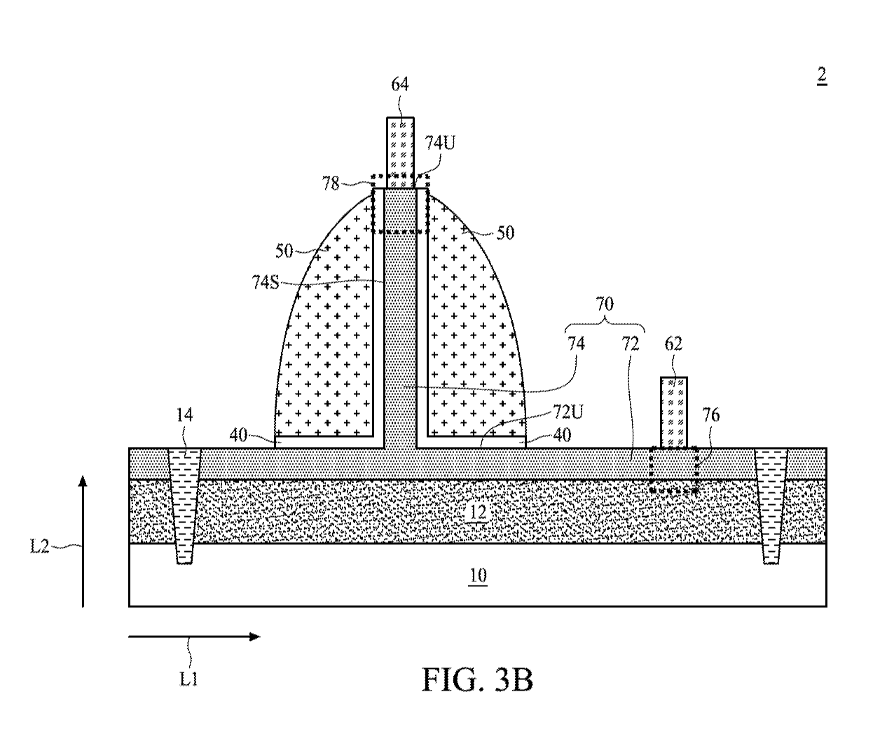

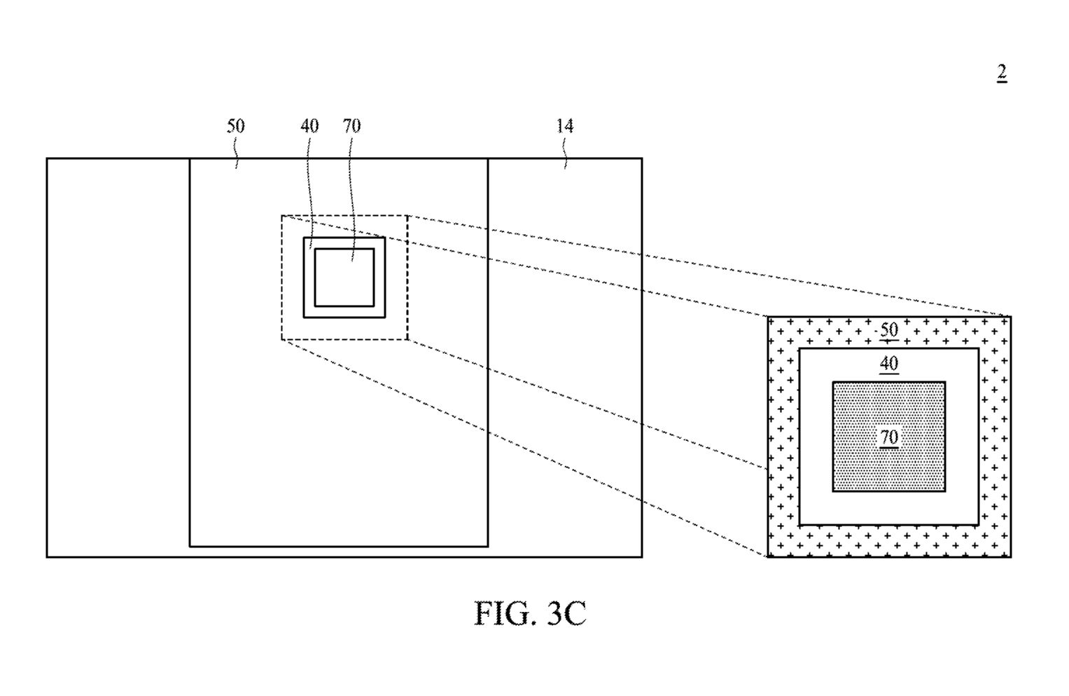

FIG. 3A, FIG. 3B and FIG. 3C are schematic diagrams of a junctionless transistor device, in accordance with some embodiments of the present disclosure, wherein FIG. 3A is a perspective view of a junctionless transistor device, FIG. 3B is a cross-sectional view of a junctionless transistor device along a line A-A of FIG. 3A, and FIG. 3C is a top view of a junctionless transistor device. As shown in FIG. 3A, FIG. 3B and FIG. 3C, the junctionless transistor device 2 includes a semiconductor substrate 10, a channel 70, a first source/drain 76, a second source/drain 78, a gate 50 and a gate dielectric layer 40. In some embodiments, the semiconductor substrate 10 my have a second doping type such as P type. In some embodiments, the semiconductor is substrate 10 may further include a doped well 12 under the channel 70. In some embodiments, the doped well 12 may have the second doping type such as P type. In some embodiments, the doping concentration of the doped well 12 may be higher than the doping concentration of the semiconductor substrate 10, and lower than the doping concentration of the channel 70. In some exemplary embodiments, the doping concentration of the doped well 12 is about 1.375*10¹⁷ atoms/cm³, but the present disclosure is not limited thereto. In some embodiments, the junctionless transistor device 2 may further include an isolation structure 14 such as a shallow trench isolation (STI) in the semiconductor substrate 10.

The channel 70 is disposed over the semiconductor substrate 10. In some embodiments, the channel 70 includes a first channel 72 and a second channel 74. The first channel 72 may extend in a lateral direction L1 substantially parallel to a surface 10S of the semiconductor substrate 10. The second channel 74 may extend in a vertical direction L2 substantially perpendicular to the surface 10S of the semiconductor substrate 10. The first channel 72 and the second channel 74 are in contact at one end, and the channel 70 has a first doping type such as N type. In some exemplary embodiments, the thickness of the channel 70, e.g., the thickness of the second channel 74, is about 5 nm, but the present disclosure is not limited thereto. In some exemplary embodiments, the length of the channel 70, e.g., the length of the first channel 72 plus the length of the second channel 74, is about 100 nm, but the present disclosure is not limited thereto.

In some embodiments, the first source/drain 76 is disposed over the semiconductor substrate, and is in contact with the first channel 72. In some embodiments, the second source/drain 78 is disposed over the second channel 74, and is in contact with the second channel 74. The first source/drain 76 and the second source/drain 78 have the same first doping type as the channel 70 such that a functionless interface is present between the first source/drain 76 and the first channel 72 and between the second source/drain 78 and the second channel 74. In some embodiments, the doping concentration of the first source/drain 76, the doping concentration of the second source/drain 78 and the doping concentration of the channel 70 are substantially the same. In some exemplary embodiments, the doping concentration of the first source/drain 76, the second source/drain 78 and the channel 70 is about 1*10¹⁹ atoms/cm³, but the present disclosure is not limited thereto.

The gate 50 is disposed over an upper surface 72U of the first channel 72 and side surfaces 74S of the second channel 74. The gate 50 may expose an upper surface 74U of the second channel 74. In some embodiments, the gate 50 has the second doping type such as P type opposite to the first doping type. In some embodiments, the doping concentration of the gate 50 is higher than the doping concentration of the channel 70. In some exemplary embodiments, the doping concentration of the gate 50 is about 1*10²⁰ atoms/cm³, but the present disclosure is not limited thereto.

The gate dielectric layer 40 is disposed between the gate 50 and the channel 70. In some embodiments, the gate dielectric layer 40 may include an oxide layer such as a silicon oxide layer. In some exemplary embodiments, the thickness of the gate dielectric layer 40 may be about 1 nm, but the present disclosure is not limited thereto. The doping concentrations of the gate 50, the channel 70, the first source/drain 76 and the second source/drain 78, the thickness of the gate dielectric layer 40, and the thickness of the channel 70 may be configured to adjust the location of the depletion region, such that the junctionless transistor device 2 is in a “normally off” state, i.e., the threshold voltage (Vt) is a positive value.

In some embodiments, the junctionless transistor device 2 may further include a first electrical contact 62 electrically connected to the first source/drain 76, and a second electrical contact 64 electrically connected to the second source/drain 78 for applying or receiving voltage. In some embodiments, the junctionless transistor device 2 may further include another electrical contact (not shown) electrically connected to the gate 50 for applying voltage to the gate 50.

In some embodiments, the gate 50 may surround the side surfaces 74S of the second channel 74 to form a gate-all-around (GA) structure. Accordingly, a channel width of the channel 70 is substantially equal to the perimeter of the second channel 74. For example, the second channel 74 may have a cuboid structure, and all four side surfaces 74S may be surrounded by the gate 50 as shown in FIG. 3C.

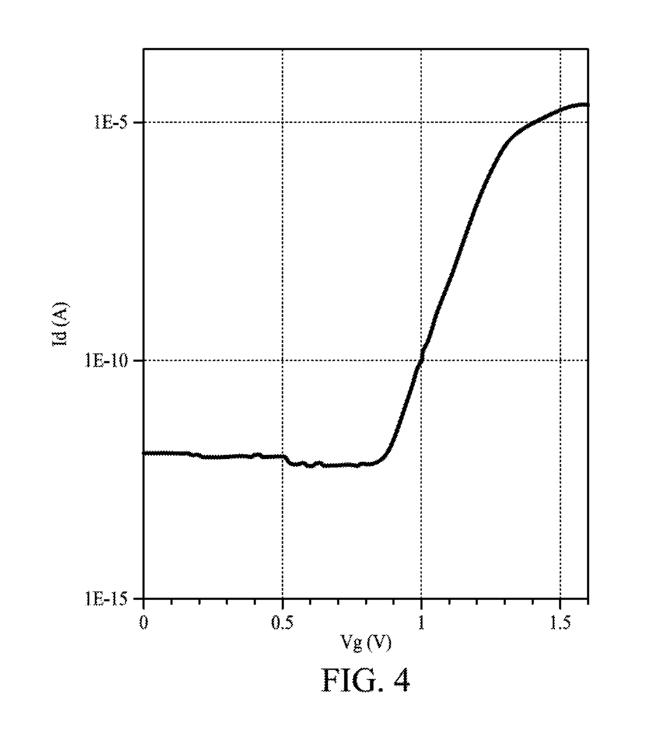

FIG. 4 is a plot illustrating an Id-Vg curve of a junctionless transistor device when Vd=1V, in accordance with some embodiments of the present disclosure. As shown in FIG. 4, the drain current (Id) of the junctionless transistor device is greater when a lower gate voltage (Vg=1.6V) is applied. The high drain current shows that the junctionless transistor device has greater carrier mobility.

In some embodiments of the present disclosure, the junctionless transistor device is a gate-all-around junctionless field effect transistor (GAAJLFET) device with a vertical channel structure. The GAAJLFET device is advantageous for its lower thermal budget, lower leakage current, greater on/off ratio and greater swing. The vertical channel structure can conserve layout area, and can be integrated into various electronic device fabrications such as DRAM fabrication.

In contrast, an FET transistor device with PN junction faces short channel effect (SCE) when scaling down, and the SCE may result in high leakage current, worse subthreshold swing and Drain Induced Barrier Lowering (DIBL) effect.

One aspect of the present disclosure provides a junctionless transistor device including a semiconductor substrate, a channel, a first source/drain, a second source/drain, a gate and a gate dielectric layer. The semiconductor substrate has a surface. The channel is disposed over the semiconductor substrate. The channel includes a first channel extending in a lateral direction substantially parallel to the surface of the semiconductor substrate, and a second channel extending in a vertical direction substantially perpendicular to the surface of the semiconductor substrate. The first channel and the second channel are in contact at one end, and the channel has a first doping type. The first source/drain is disposed over the semiconductor substrate, and is in contact with the first channel, wherein the first source/drain has the first doping type. The second source/drain is disposed over the second channel, and is in contact with the second channel. The second source/drain has the first doping type. The gate is disposed over an upper surface of the first channel and side surfaces of the second channel, and the gate has a second doping type opposite to the first doping type. The gate dielectric layer is disposed between the gate and the channel.

Another aspect of the present disclosure provides a method for preparing a functionless transistor device. The method includes the following steps. A semiconductor substrate is provided. A semiconductor doped structure is formed over the semiconductor substrate. The semiconductor doped structure has a first doping type. The semiconductor doped structure includes a first doped structure extending in a lateral direction substantially parallel to a surface of the semiconductor substrate, and a second doped structure extending in a vertical direction substantially perpendicular to the surface of the semiconductor substrate. A gate dielectric layer and a gate are formed over the semiconductor doped structure. The gate has a second doping type opposite to the first doping type.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps. in described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A junctionless transistor device, comprising:
a semiconductor substrate having a surface;
a channel disposed over the semiconductor substrate, wherein the channel comprises a first channel extending in a lateral direction substantially parallel to the surface of the semiconductor substrate, and a second channel extending in a vertical direction substantially perpendicular to the surface of the semiconductor substrate, wherein the first channel and the second channel are in contact at one end, and the channel has a first doping type;
a first source/drain disposed over the semiconductor substrate, and in contact with the first channel, wherein the first source/drain has the first doping type;
a second source/drain disposed over the second channel, and in contact with the second channel, wherein the second source/drain has the first doping type;
a gate disposed over an upper surface of the first channel and side surfaces of the second channel, wherein the gate has a second doping type opposite to the first doping type; and
a gate dielectric layer disposed between the gate and the channel.

2. The junctionless transistor device of claim 1, wherein a doping concentration of the first source/drain, a doping concentration of the second source/drain and a doping concentration of the channel are substantially the same.

3. The junctionless transistor device of claim 2, wherein a doping concentration of the gate is higher than a doping concentration of the channel.

4. The junctionless transistor device of claim 1, wherein the semiconductor substrate includes a doped well under the channel, and the doped well has the second doping type.

5. The junctionless transistor device of claim 4, wherein a doping concentration of the doped well is lower than a doping concentration of the channel.

6. The junctionless transistor device of claim 1, further comprising a first electrical contact electrically connected to the first source/drain, and a. second electrical contact electrically connected to the second source/drain.

7. The junctionless transistor device of claim 1, wherein the gate surrounds a plurality of side surfaces of the second channel.

8. A method for preparing a junctionless transistor device, comprising:
providing a semiconductor substrate;
forming a semiconductor doped structure over the semiconductor substrate, wherein the semiconductor doped structure has a first doping type, and the semiconductor doped structure comprises a first doped structure extending in a lateral direction substantially parallel to a surface of the semiconductor substrate, and a second doped structure extending in a vertical direction substantially perpendicular to the surface of the semiconductor substrate; and
forming a gate dielectric layer and a gate over the semiconductor doped structure, wherein the gate has a second doping type opposite to the first doping type.

9. The method of claim 8, wherein the forming the semiconductor doped structure over the semiconductor substrate comprises:
forming a doped region having the first doping type in the semiconductor substrate; and
patterning the doped region to form the semiconductor doped structure.

10. The method of claim 8, Wherein the gate dielectric layer and the gate cover an upper surface of the first doped structure and side surfaces of the second doped structure, and expose an upper surface of the second doped structure.

11. The method of claim 10, wherein the forming the gate dielectric layer and the gate over the semiconductor doped structure comprises:
forming the gate dielectric layer over the semiconductor doped structure;
forming the gate over the gate dielectric layer;
doping the gate; and
partially removing the gate and the gate dielectric layer to expose the upper surface of the second doped structure.

12. The method of claim 11, Wherein the forming the gate dielectric: layer over the semiconductor doped structure comprises thermally growing a thermal oxide layer over the semiconductor doped structure.

13. The method of claim 8, wherein a doping concentration of the first doped structure and a doping concentration of the second doped structure are substantially the same.

14. The method of claim 8, wherein a doping concentration of the gate is higher than a doping concentration of the semiconductor doped structure.

15. The method of claim 8, wherein an end of the first doped structure is configured as a first source/drain, an end of the second doped structure is configured as a second source/drain, and the first doped structure and the second doped structure are configured as a channel.
